(19) United States
(12) Patent Application Publication
(10) Pub. No.: US 2010/0163836 A1
(43) Pub. Date: Jul. 1, 2010

(54) LOW-VOLUME PHASE-CHANGE MATERIAL MEMORY CELL

(76) Inventor: Daniel R. Shepard, North Hampton, NH (US)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/643,278

(22) Filed: Dec. 21, 2009

Related U.S. Application Data
(60) Provisional application No. 61/204,076, filed on Dec. 31, 2008.

(51) Int. Cl. H01L 45/00; H01L 21/20

(52) U.S. Cl. 257/5; 438/482; 257/E45.002; 257/E21.09

(57) ABSTRACT

A memory device includes a memory array comprising a plurality of storage locations disposed above a plurality of generally parallel lines, where each storage location comprises a programmable material disposed on a sidewall of a conductive element.

### CROSS-REFERENCE TO RELATED APPLICATION

This application claims priority to and the benefit of, and incorporates herein by reference in its entirety, U.S. Provisional Patent Application No. 61/204,076, which was filed on Dec. 31, 2008.

### TECHNICAL FIELD

In various embodiments, the present invention relates to the design and operation of solid-state memory arrays, and more particularly to memory arrays incorporating phase-change materials.

### BACKGROUND

Many types of non-volatile memory-storage cells exist in the prior art, including trapped-charge devices (e.g., flash memory) and altered-resistivity devices such as phase-change random-access memory (PRAM), resistive random-access memory (RRAM), or chalcogenide-based memories. Flash memory is relatively fast, but suffers from short data-retention times. While phase-change materials generally retain data for longer times and have access times comparable to those of flash memories, process integration of phase-change materials may challenging due to their inability to withstand elevated thermal budgets. Furthermore, PRAMs often require high voltages (and concomitant current levels) to program individual memory cells.

Different forms of RRAM utilize different dielectric materials, ranging from perovskites to transition metal oxides to chalcogenides. An RRAM device typically features a conduction path (e.g., a filament or other path formed by application of a high voltage) through a dielectric, which is normally insulating. The conduction path may be broken (resulting in high resistance) and re-formed (resulting in low resistance) by appropriate voltages. Incorporating a resistive-change material in a memory cell facilitates alteration of the resistivity of the current path through the cell, thereby changing the state of the stored bit or bits. Examples of such resistive-change materials are set forth in, e.g., U.S. Pat. Nos. 6,531,371, 6,867,996, 6,870,755, 6,946,702, 7,067,865, 7,157,750, and 7,292,469, the entire disclosure of each of which is incorporated by reference.

PRAM devices incorporate phase-change materials (PCMs) such as alloys of germanium, antimony, and tellurium (GST or, typically, Ge₂Sb₂Te₅). Exemplary devices incorporating GST are disclosed in, e.g., U.S. Pat. Nos. 3,983,542, 4,646,266, and 5,414,271, the entire disclosures of which are incorporated by reference. GST may be placed into its crystalline phase via application of a current through the cell sufficient to heat the GST, followed by a slow diminution of the current and associated heat. The slow cooling of the GST permits the atoms of the GST to align in a crystalline phase. In order to place the GST into its amorphous state, the current is cut off abruptly. The resulting rapid cooling traps the GST atoms into the amorphous phase, as they lack sufficient time to rearrange. Intermediate phases can be achieved by current reduction and associated cooling at rates between the two above-described points. Unfortunately, many PRAM devices require exceptionally large current levels to change the phase of individual memory cells, hampering their broad adoption in the memory industry.

### SUMMARY

In various embodiments, the present invention addresses the large current density required to write information to (or erase information from) a phase-change memory cell.

In particular, embodiments of the present invention limit the cross-sectional area of the memory cell in order to increase the effective current density through the phase-change material in the cell.

In an aspect, embodiments of the invention feature a memory device including a memory array that includes or consists essentially of a plurality of storage locations disposed above a plurality of generally parallel lines. Each storage location includes a programmable material disposed on a sidewall of a conductive element.

Embodiments of the invention may include one or more of the following. The sidewall may be substantially vertical. At each storage location, the programmable material may be disposed substantially only on the sidewall of the conductive element. The conductive element may include or consist essentially of a dielectric material and a conductive material thereover. The conductive element may be disposed over a memory element, and the programmable material may electrically connect the conductive material and the memory cell contact. The memory cell contact and the conductive material may be misaligned. The programmable material may include or consist essentially of a chalcogenide alloy, e.g., an alloy including or consisting essentially of germanium, antimony, and/or tellurium. The programmable material may include or consist essentially of a dielectric material, a transition-metal oxide, and/or a perovskite. The memory array may be a single block of a multiple-block memory circuit. The memory circuit may have a three-dimensional topology.

In another aspect, embodiments of the invention feature a method of forming a memory element. A substrate having a memory cell contact thereon is provided, and a conductive element is formed over only a portion of the memory cell contact, thereby leaving exposed an area of the memory cell contact. The memory cell contact and the conductive element are electrically connected by forming a programmable material over at least the exposed area of the memory cell contact. The programmable material may be formed by depositing a layer of the programmable material over the substrate and anisotropically etching the layer of programmable material. The exposed area of the memory cell contact may be substantially covered by the programmable material.

In yet another aspect, embodiments of the invention feature a method of forming a memory element. A substrate having a memory cell contact thereon is provided, a conductive element having at least one sidewall is formed over the substrate, and a programmable material is formed on at least the at least one sidewall. The at least one sidewall may be substantially vertical. The programmable material may be formed by depositing a layer of the programmable material over the substrate and anisotropically etching portions of the layer of programmable material not contacting the at least one sidewall. The conductive element may be formed over only a portion of the memory cell contact, thereby leaving exposed an area of the memory cell contact. The programmable material may be disposed in contact with the exposed area and may electrically connect the memory cell contact and the conductive element.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawing, in which:

FIG. 1 is a schematic diagram of a memory device in accordance with various embodiments of the invention;

FIG. 2 is a schematic cross-section of an exposed memory cell top contact, in accordance with various embodiments of the invention;

FIG. 3 depicts the schematic of FIG. 2 after deposition of a dielectric material and a top conductor material, in accordance with various embodiments of the invention;

FIG. 4 depicts the schematic of FIG. 3 after patterning and etching the top conductor material and the dielectric material, in accordance with various embodiments of the invention;

FIG. 5 depicts the schematic of FIG. 4 after deposition of a phase-change material, in accordance with various embodiments of the invention; and

FIG. 6 is a schematic cross-section of the memory cell after the phase-change material has been etched to decrease its cross-sectional area, thus enabling increased current density therethrough in accordance with various embodiments of the invention.

### DETAILED DESCRIPTION

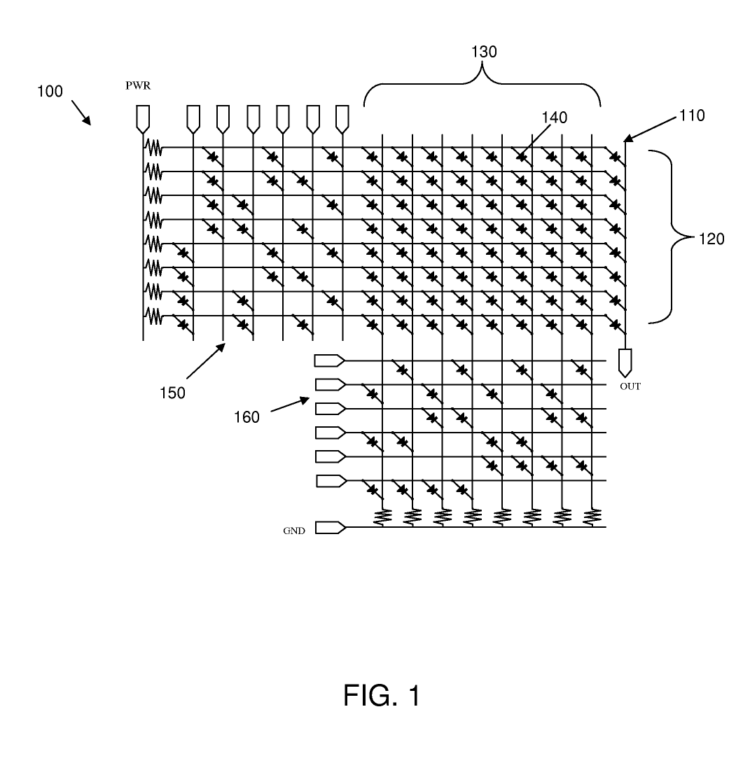

FIG. 1 depicts an exemplary memory device 100 compatible with embodiments of the present invention. Memory device 100 includes a memory array 110 of memory locations, or bits, defined by the intersection of memory rows 120 and memory columns 130. A storage element 140, which may include or consist essentially of, e.g., a diode or other current-steering device in series with a phase-change or resistive-change material, is disposed proximate at least some of the memory locations. In various embodiments, a storage element 140 is present proximate each of the memory locations in order to prevent the propagation of “back currents” through the memory array 110. Memory device 100 also may include a row decoder 150 and/or a column decoder 160. Each of row decoder 150 and column decoder 160 preferably includes or consists essentially of a patterned array of non-linear elements such as diodes, transistors, or other rectifying devices.

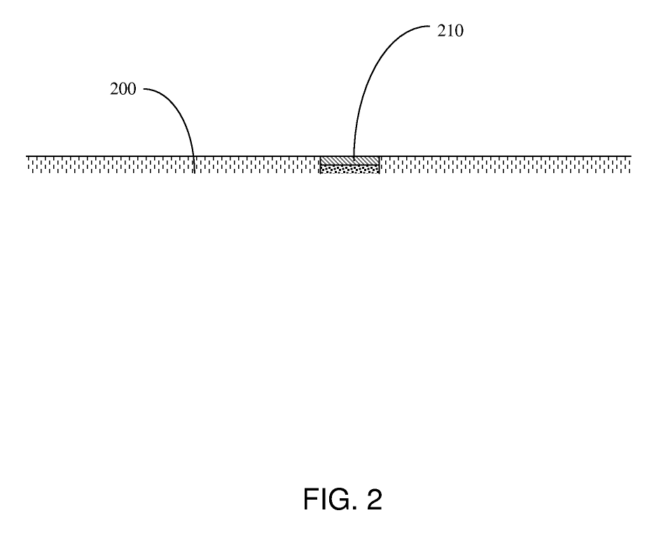

FIG. 2 depicts a single partially fabricated storage cell 140 (herein also referred to as a “memory cell”) on a substrate 200 during the fabrication of memory device 100. Typically the memory cell will be one of many memory cells in memory array 110, but only a single cell is illustrated for ease of depiction. The substrate 200 may include or consist essentially of one or more semiconductor materials, e.g., silicon, gallium arsenide, or indium phosphide, and may incorporate any number of pre-fabricated (or contemporaneously fabricated) electronic devices on, above, or below the level where the memory cell is being fabricated. Shown in FIG. 2 is a memory cell top contact 210, typically below which is, e.g., a current-steering device (not shown) associated with the memory cell and the row or column on which it is located, and above which the information-storage portion of the cell is to be formed (as described below). Top contact 210 may include or consist essentially of one or more conductive materials, e.g., doped polysilicon or a metal. Memory cells fabricated in accordance with embodiments of the present may be similar to those disclosed in U.S. Patent Application Publication No. 2009/0161420 and U.S. patent application Ser. Nos. 12/543,086 and 12/581,555, the entire disclosures of which are incorporated by reference herein.

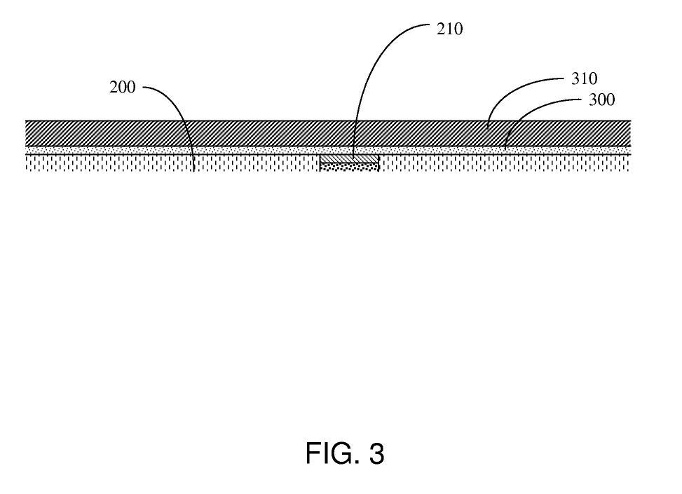

Referring to FIG. 3, a dielectric material 300 and a top conductor material 310 are formed over top contact 210 and substrate 200. Dielectric material 300 may include or consist essentially of an insulating material such as an oxide or a nitride. Top conductor material 310 may include or consist essentially of a conductive material, e.g., doped polysilicon or a metal. The thickness of dielectric material is selected to prevent conduction between top contact 210 and top conductor material 310 during normal operation of the memory cell (as described below), either by direct conduction or by charge tunneling. Top conductor material 310 is generally patterned to form the row or column along which the memory cell is located (while the other of the row and column is located below top contact 210 and the current-steering device of the cell, as described above).

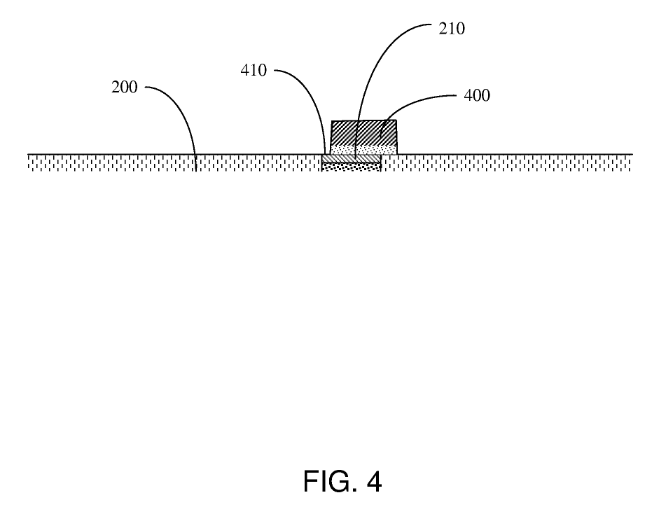

Referring to FIG. 4, top conductor material 310 and dielectric material 300 are patterned by, e.g., conventional photolithography and etching processes, to form a conductive element 400 above top contact 210 and substrate 200. The sidewalls of conductive element 400 may be substantially vertical (i.e., forming an approximately 90° angle with the surface of substrate 200), or may be non-vertical (i.e., forming an angle greater than 90°, e.g., less than approximately 135°, with respect to the surface of substrate 200). During its formation, conductive element 400 is deliberately misaligned with respect to top contact 210 (e.g., the position of conductive element 400 is defined via the photolithography masks or during photolithographic exposure to be offset such that the edge of conductive element 400 falls between the edge of top contact 210 and the center of top contact 210), thus exposing exposed area 410 of top contact 210. The size of exposed area 410 at least partially facilitates the high current density in the final phase-change memory element (as described below). In some embodiments, the width of conductive element 400 is less than the width of top contact 210, and exposed area 410 includes area on more than a single side of conductive element (up to and including an area formed around substantially the entire perimeter of conductive element 400).

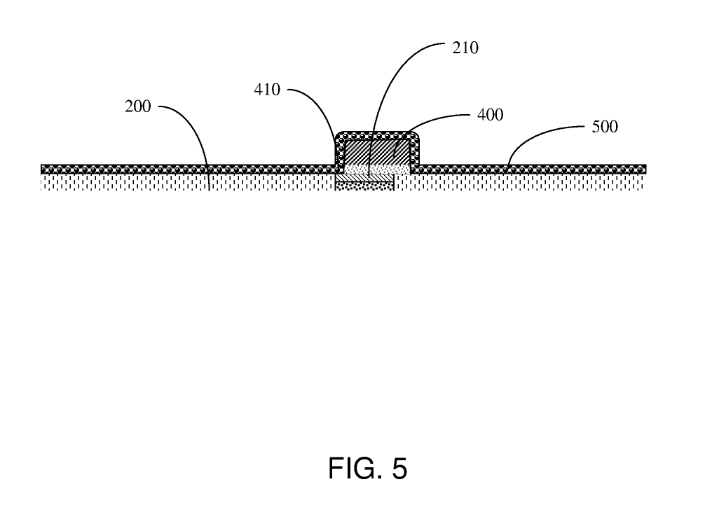

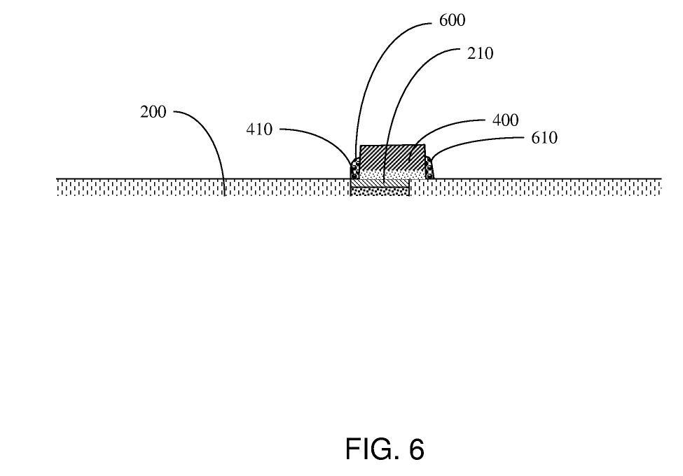

Referring to FIGS. 5 and 6, a layer of a phase-change material 500 is formed over conductive element 400, top contact 210, and substrate 200 by, e.g., conformal deposition. The deposition may be performed by, e.g., sputtering, chemical-vapor deposition, or atomic layer deposition. In an embodiment, the thickness of phase-change material 500 is approximately the same as the width of exposed area 410 such that, after portions of phase-change material 500 not in contact with conductive element 400 are removed, the surface of exposed area 410 is substantially covered by phase-change material 500. The thickness of phase-change material 500 is preferably larger than the thickness of dielectric material 300, in order to promote electrical contact through the phase-change material 500 during operation of the memory cell (as described below).

Phase-change material 500 is then anisotropically etched by, e.g., plasma etching, removing portions of phase-change material 500 other than those on the sidewalls of conductive element 400. Because phase-change material 500 is etched anisotropically, portions on the sidewalls of conductive element 400 remain unetched due to the larger effective vertical thickness of phase-change material 500 in those regions. At least a portion of the remaining phase-change material 600 contacts both the top contact 210 (in exposed area 410) and top conductor material 310 of conductive element 400 (remaining phase-change material 610 also remains on the other sidewall of conductive element 400). The volume of this portion corresponds to the volume of phase-change material to which current is applied when programming, e.g., writing or erasing, the memory cell. In embodiments where it is desired only to have phase-change material 600 on a single sidewall of conductive element 400, phase-change material 500 may be anisotropically etched at a non-perpendicular angle to the surface of substrate 200. For example, in the embodiment illustrated in FIG. 6, the anisotropic etch may substantially remove phase-change material 610 while leaving phase-change material 600 intact.

After formation of phase-change material 600, 610, a dielectric material (not shown) may be formed over phase-change material 600, 610 and conductive element 400 in order to encapsulate the memory cell. During operation of the memory element, current flows between top contact 210 and conductive element 400 through exposed area 410 and phase-change material 600. The limited volume of phase-change material 600 increases the current density flowing therethrough, decreasing the amount of current required to program (e.g., write to or erase) the memory cell. The current heats the phase-change material, facilitating the programming thereof with the desired information (as described in more detail above). Programming (e.g., erasing) of several memory cells may be achieved by either substantially instantaneous heating of the memory cells, or by successive heating of memory cells that are in close proximity (as the heat generated at one memory cell may increase the temperature of neighboring cells incrementally, thus decreasing the additional amount of heat required to program those cells). Alternatively, an entire memory array of such devices may be programmed simultaneously by external heating of the entire memory device the array is disposed within. In various embodiments, fabrication of the memory cells features deposition of the phase-change material after all other processing steps (e.g., for formation of the current-steering devices, conductors, and other devices thereunder) at temperatures above approximately 400° C. Such processes preserve the characteristics and integrity of the phase-change material, as some phase-change materials (e.g., GST) may deteriorate due to out-diffusion at temperatures above approximately 400° C.

Various embodiments of the invention feature programmable materials such as resistive-change materials in addition to, or instead of, the phase-change materials utilized in the illustrative embodiment. Embodiments may be implemented with cross-point memory arrays and these arrays may be one of many tiles or sub-arrays in a larger device or an array within a three-dimensional arrangement of arrays or tiles. The memory cells may include various non-linear elements, e.g., transistors, field-emitters, diodes, or any other device that conducts current better in one direction than the other for a given applied voltage. Orientation of the array may be rotated, i.e., the “rows” may be “columns,” or vice versa.

Embodiments of the present invention may be utilized in memory devices used in systems for storing digital text, digital books, digital music, digital audio, digital photography (wherein one or more digital still images is stored, including sequences of digital images), digital video, digital cartography (wherein one or more digital maps is stored), and any other digital or digitized information as well as any combinations thereof. These memory devices may be embedded, removable, or removable and interchangeable among other devices that access the data therein. They may be packaged in any variety of industry-standard form factors such as Compact Flash, Secure Digital, MultiMedia Cards, PCMCIA Cards, Memory Stick, and/or any of a large variety of integrated circuit packages including Ball Grid Arrays, Dual In-Line Packages (DIPs), SOICs, PLCCs, TQFPs, and the like, as well as in proprietary form factors and custom-designed packages. These packages may contain just the memory chip, multiple memory chips, or one or more memory chips along with other logic devices or other storage devices such as PLDs, PLAs, micro-controllers, microprocessors, memory controller chips or chip-sets, or other custom or standard circuitry. Packaging may include a connector for making electrical contact with another device when the device is removable or removable and interchangeable.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. A memory device comprising:
a memory array comprising a plurality of storage locations disposed above a plurality of generally parallel lines,
wherein each storage location comprises a programmable material disposed on a sidewall of a conductive element.

2. The memory device of claim 1, wherein the sidewall is substantially vertical.

3. The memory device of claim 1, wherein, at each storage location, the programmable material is disposed substantially only on the sidewall of the conductive element.

4. The memory device of claim 1, wherein the conductive element comprises a dielectric material and a conductive material thereover, the conductive element is disposed over a memory cell contact, and the programmable material electrically connects the conductive material and the memory cell contact.

5. The memory device of claim 4, wherein the memory cell contact and the conductive material are misaligned.

6. The memory device of claim 1, wherein the programmable material comprises a chalcogenide alloy.

7. The memory device of claim 6, wherein the chalcogenide alloy comprises at least one of germanium, antimony, or tellurium.

8. The memory device of claim 1, wherein the programmable material comprises at least one of a dielectric material, a transition-metal oxide, or a perovskite.

9. The memory device of claim 1, wherein the memory array is a single block of a multiple-block memory circuit.

10. The memory device of claim 9, wherein the memory circuit has a three-dimensional topology.

11. A method of forming a memory element, the method comprising:
providing a substrate having a memory cell contact thereon;
forming a conductive element over only a portion of the memory cell contact, thereby leaving exposed an area of the memory cell contact; and
electrically connecting the memory cell contact and the conductive element by forming a programmable material over at least the exposed area of the memory cell contact.

12. The method of claim 11, wherein forming the programmable material comprises depositing a layer of the programmable material over the substrate and anisotropically etching the layer of programmable material.

13. The method of claim 11, wherein the conductive element comprises a conductive material disposed over a dielectric material.

14. The method of claim 11, wherein the exposed area of the memory cell contact is substantially covered by the programmable material.

15. A method of forming a memory element, the method comprising:
providing a substrate having a memory cell contact thereon;
forming, over the substrate, a conductive element having at least one sidewall; and
forming a programmable material on at least the at least one sidewall.

16. The method of claim 15, wherein the at least one sidewall is substantially vertical.

17. The method of claim 15, wherein forming the programmable material comprises depositing a layer of the programmable material over the substrate and anisotropically etching portions of the layer of programmable material not contacting the at least one sidewall.

18. The method of claim 15, wherein the conductive element is formed over only a portion of the memory cell contact, thereby leaving exposed an area of the memory cell contact, and wherein the programmable material is disposed in contact with the exposed area.

19. The method of claim 18, wherein the programmable material electrically connects the memory cell contact and the conductive element.
